(19) United States
(12) Patent Application Publication
(10) Pub. No.: US 2026/0090417 A1
(43) Pub. Date: Mar. 26, 2026

(54) PACKAGE FOR A POWER CIRCUIT

(71) Applicant: Monolithic Power Systems, Inc., Kirkland, WA (US)

(72) Inventors: Hunt Hang Jiang, Saratoga, CA (US); Yingjiang Pu, Chengdu (CN)

(21) Appl. No.: 18/896,495

(22) Filed: Sep. 25, 2024

(51) Int. Cl. H01L 23/538; H01L 23/00; H01L 23/367; H01L 25/10

(52) U.S. Cl. CPC H10W 70/65; H10W 40/22; H10W 70/611; H10W 90/00; H10W 90/724

(57) ABSTRACT

This power circuit package includes a patterned conductive layer arranged a first side of a semiconductor substrate. This patterned conductive layer is configured to be electrically coupled to a first die arranged on the substrate, a heat sink arranged on the substrate, and a second die embedded in the substrate. Terminals, vias and pads of patterned conductive layer form different conductive net of the package. By setting the heat sink on the “busiest” net, the overall on-resistance of a circuit can be reduced.

### TECHNICAL FIELD

Embodiments of the present invention relate to semiconductor package, and more particularly relate to a power circuit package.

### BACKGROUND OF THE INVENTION

A trend of power circuit package is driven by the need for more efficient and compact package across various industries, including consumer electronics and automotive. Reducing the conduction resistance in such package is very meaningful since lower resistance leads to less power loss in the form of heat during operation, which is crucial for maintaining efficiency and extending the lifespan of electronic components. Additionally, enhancing the thermal performance of this power circuit package is essential to dissipate the heat generated effectively, ensuring the reliability and stability of the system. As such, the design of power circuit package is increasingly focused on making tradeoffs between miniaturization, high power output, low resistance, and superior heat management.

### SUMMARY OF THE INVENTION

Embodiments of the present invention are directed to a power circuit package. The power circuit package includes a substrate, a first die, a second die and a heat sink. The substrate further includes a first pattern conductive layer on its second side and a second pattern conductive layer on its first side. The first pattern conductive layer includes a first terminal, a second terminal and a third terminal. The first die and the heat sink are electrically connected to the second pattern conductive layer. The second die is embedded in the substrate and electrically coupled to the second pattern conductive layer too. The first terminal is electrically coupled to the first die, the second terminal is electrically coupled to the first die and second die, and the third terminal is electrically coupled to the second die.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is a cross-section view illustrating a power circuit package in accordance with an example embodiment of the present disclosure.

FIG. 2 is a cross-section view illustrating the power circuit package in accordance with an example embodiment of the present disclosure.

FIG. 3 is an illustration of outlines of the power circuit package body in accordance with an example embodiment of the present disclosure.

FIG. 4A is a schematic diagram of a charging phase of a Buck converter.

FIG. 4B is a schematic diagram of a discharging phase of the Buck converter.

FIG. 5A is a cross-section view illustrating a power circuit package configured for a Buck converter and additionally shows the current direction during a charging phase of the Buck converter.

FIG. 5B is a cross-section view illustrating the power circuit package configured for a Buck converter and additionally shows the current direction during a discharging phase of the Buck converter.

FIG. 6A is a schematic diagram of a charging phase of a Boost converter.

FIG. 6B is a schematic diagram of a discharging phase of the Boost converter.

FIG. 7A is a cross-section view illustrating a power circuit package configured for a Boost converter and additionally shows the current direction during a charging phase of the Boost converter.

FIG. 7B is a cross-section view illustrating the power circuit package configured for a Boost converter and additionally shows the current direction during a discharging phase of the Boost converter.

FIG. 8 is a cross-section view illustrating a power circuit package 800 in accordance with an example embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phases “one embodiment”, “an embodiment”, “an example” and “examples” are not necessarily directed to the same embodiment or example. Furthermore, the features, structures, or characteristics may be combined in one or more embodiments or examples. Throughout the specification and claims, the ordinal numbers “first,” “second,” and “third” are intended to indicate different features and are not intended to indicate the order. For example, “a second conductive net” is a conductive net different from the “a first conductive net”.

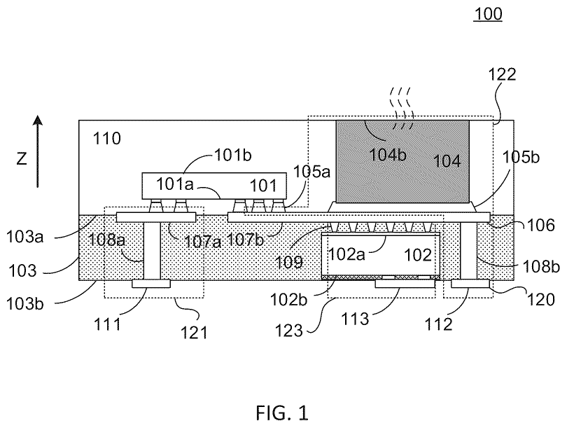

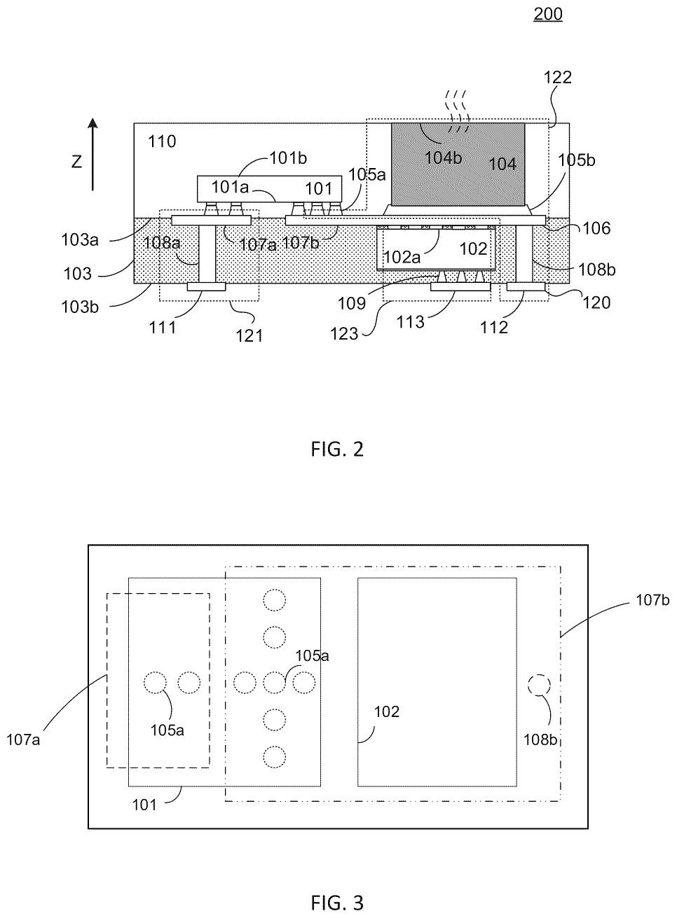

An exemplary power circuit package structure is illustrated in FIGS. 1, 2 and 3, according to some embodiments of this disclosure. FIG. 1 is a schematic view of the power circuit package 100. FIG. 2 is schematic view of another proposed power circuit package 200. FIG. 3 is an illustration of the outlines of an example power circuit package 100. The following description collectively references each of FIGS. 1, 2 and 3.

FIG. 1 illustrates a power circuit package 100 in accordance with an embodiment of the present disclosure. The power circuit package 100 includes a first die 101, a second die 102, a substrate 103 and a heat sink 104. The substrate 103 may include a first side 103a and a second side 103b opposite to the first side 103a. The first side 103a is a side which, when the first die 101 is mounted to the substrate 103, faces the first die 101, while the second side 103b is a side which faces away from the first die 101. Both the first die 101 and the heat sink 104 are formed on the first side 103a, while the second die 102 is embedded in the substrate 103. A second side 104b of the heat sink may expose from encapsulation material 110 to ensure better heat dissipation in a direction perpendicular to substrate 103 (i.e., Z-axis direction in FIG. 1). A first patterned conductive layer 120 may expose on the second side 103b of the substrate 103. The first patterned conductive layer 120 may include a first terminal 111, a second terminal 112 and a third terminal 113. The first terminal 111 may be electrically coupled to the first die 101. The third terminal 113 may be electrically coupled to the second die 102. The second terminal 112 may be electrically coupled to both the first die 101 and the second die 102.

The first die 101 may include a first side 101a having electrodes formed thereof and a second side 101b opposite to the first side 101a. The first side 101a is a side which, when the first die 101 is mounted to the substrate 103, faces the substrate 103, while the second side 101b is a side which faces away from the substrate 103. In one embodiment, the electrodes of the first die 101 are coupled through solders 105a to a second patterned conductive layer 106 on the first side 103a of the substrate 103. While only five solders 105a are shown in FIG. 1, there may be tens or hundreds of solders providing electrical connection between the first die 101 and the second patterned conductive layer 106.

The second patterned conductive layer 106 may consist of several pads, such as a first pad 107a and a second pad 107b, of the following materials: copper, aluminum, gold or any suitable alloys. Those pads of the second patterned conductive layer 106 are dielectrically isolated from each other so that they could be configured to be connected or coupled to different potentials. Traces may be arranged between pads that are intentionally designed to interconnect to ensure they are connected and form a common node in the circuit. These pads may be metal structures formed in a same manufacturing step, or they may be located on a same horizontal plane, which is why they are considered as a whole and referred to as the second patterned conductive layer 106, even though they are not a continuous layer of metal. However, these pads are not necessarily formed in a same manufacturing step, nor located on a same horizontal plane.

FIG. 3 shows an illustration of the outlines of an example power circuit package of this disclosure. As shown in FIG. 3, when observed from a direction perpendicular to the first surface 103a of the substrate 103 (i.e., the Z-axis direction of FIG. 1), the first pad 107a of the first pattern conductive layer 106 may be arranged partially overlap with the projection area of the first chip 101 on the first surface 103a to facilitate shortest connection between the first chip 101 and the second patterned conductive layer 106. The second pad 107b of the first pattern conductive layer 106 may be configured to cover the whole projection area of the second chip 102 and to serve as an island for attaching a large heat sink 104. As shown in FIG. 1, solder or sintered metal 105b may be dispensed on the second pad 107b to both electrically and mechanically couple a first side 104a of the heat sink 104 to the second patterned conductive layer 106. In one embodiment, some electrodes of the first die 101 are coupled to the first pad 107a and some other electrodes of the first die 101 are coupled to the second pad 107b.

The substrate 103 may be formed of insulating material or dielectric material, such as glass, FR-4, cotton-paper reinforced epoxy, glass-reinforced epoxy or any other suitable choice. The substrate 103 may include a purity of conductive vias extending through it. As shown in FIG. 1, a first conductive via 108a is configured to electrically connected to the first pad 107a at one of its ends and electrically connected to the first terminal 111 at its another end, coupling the first terminal 111 to the first die 101 and forming a first conductive net 121 of the power circuit package 100 together with them. A second conductive via 108b is configured without the projection area of the first chip 101 and second chip 102 on the first surface 103a. The second conductive via 108b is configured to electrically connected to the second pad 107b at one of its ends and electrically connected to the second terminal 112 at its another end, coupling the second terminal 112 to the first die 101, the second die 102 and the heat sink 104 and forming a second conductive net 122 of the power circuit package 100 together with them.

The second die 102 may include a first side 102a having electrodes formed thereof and a second side 102b having electrodes formed thereof. The first side 102a is a side which, when the second die 102 is embedded in the substrate 103, faces the first side 103a of the substrate 103, while the second side 102b is a side which faces away from the first side 103a of the substrate 103. In one embodiment, as shown in FIG. 1, a plurality of third conductive vias 109 are embedded in the substrate, extending from the first side 102a to the second pad 107b to electrically couple the second patterned conductive layer 106 to the electrodes of the second die 102 on its first side 102a. Electrodes of the second die 102 on its second side 102b may be electrically coupled to the third terminal 113, forming a third conductive net 123 of the power circuit package 100 together with the plurality of third conductive vias 109 and the second die 102. However, in another embodiment, as shown in FIG. 2, a plurality of third conductive vias 109 are embedded in the substrate, extending from the second side 102b to the first patterned conductive layer 120 to electrically couple the third terminal 113 to the electrodes of the second die 102 on its second side 102b. Electrodes of the second die 102 on its first side 102a may be electrically coupled to the second pad 107b, forming a third conductive net 123 of the power circuit package 100 together with the plurality of third conductive vias 109 and the second die 102.

As mentioned above, the second conductive net 122 is a net that electrically coupled to first die 101, the second die 102 and the heat sink 104. So, it's the “busiest” net among the three nets. Setting the heat sink 104 on this net could effectively enhance the current-carrying capacity of the “busiest” net and thus reduce the overall on-resistance of the circuit. In the following, several exemplary package arrangements of circuits will be described to better elaborate this disclosure.

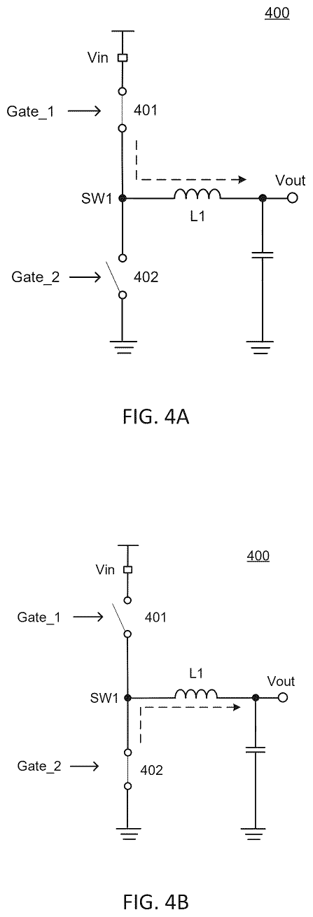

Now referring to FIG. 4A and FIG. 4B, an operation of a typical Buck converter 400 can be described in terms of two main phases: the charging phase (e.g., FIG. 4A) and the discharging phase (e.g., FIG. 4B). The Buck converter 400 may include a first switch 401 and a second switch 402 that are connected in series between an input voltage Vin and a ground GND. The first switch 401 and the second switch 402 are connected at a first switch node SW1. An inductor L1 is connected between the first switch node SW1 and an output voltage Vout. By manipulating one of the two switches to turn on and the other to turn off by gate signals (i.e., Gate_1 and Gate_2), either the input voltage Vin or the ground GND could be electrically connected to the first switch node SW1, and then conducts current flowing through the first inductor L1.

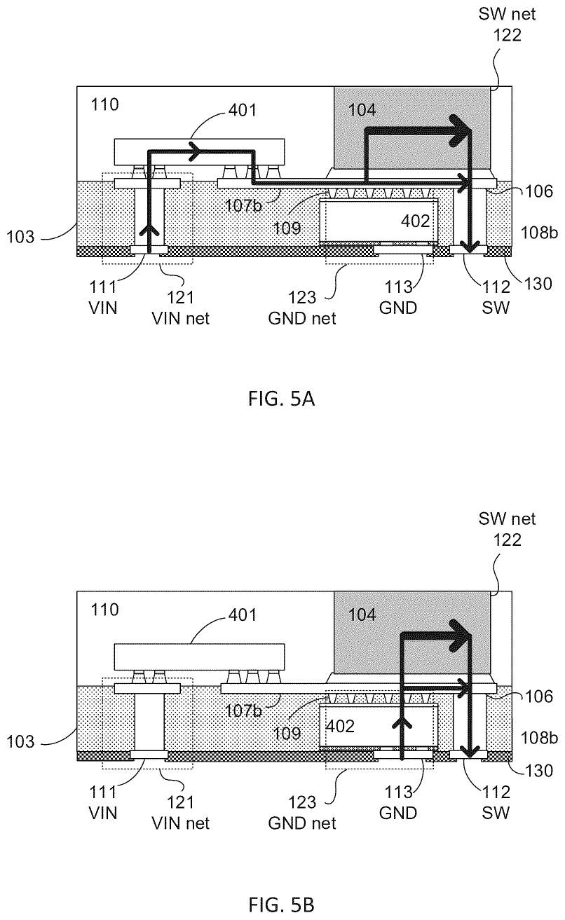

Referring to FIG. 5A and FIG. 5B, some reference numerals of FIG. 1 are replaced by reference numerals of circuit elements of Buck converter 400 while others are kept the same. In this embodiment, the power circuit package of this disclosure could be implemented for packaging the Buck converter 400 and could reduce its overall on-resistance. The first die 101 of the package 100 could be a die including the first switch 401 of the Buck convertor 400, which may be a lateral FET device. The second die 102 of the package 100 could be a die including the second switch 402 of the Buck convertor 400, which may be a vertical FET device. Besides, the first terminal 111 could be configured to be coupled to the input voltage Vin and serve as a VIN terminal of the power circuit package 100, making the first conductive net 121 become a VIN net. The second terminal 112 could be configured to be coupled to the first switch node SW1 and serve as a SW terminal of the power circuit package 100, making the second conductive net 122 become a SW net. The third terminal 113 could be configured as GND terminal of the power circuit package 100, making the third conductive net 123 become a GND net. Other elements of the Buck convertor are not shown in FIG. 5A. For example, the first inductor L1, may be configured outside the power circuit package.

Referring to FIG. 5A, during the charging phase, the second switch 402 is turned off, so that the GND net (i.e., the third conductive net 123) is decoupled with the SW net (i.e., the second conductive net 122). The current flow all the way from the VIN terminal (i.e., the first terminal 111) to the SW terminal (i.e., the second terminal 112) through the VIN net (i.e., the first conductive net 121) and the SW net (i.e., the second conductive net 122). Referring to FIG. 5B, during the discharging phase, the first switch 401 is turned off, so that the VIN net (i.e., the first conductive net 121) is decoupled with the SW net (i.e., the second conductive net 122). The current flow all the way from the GND terminal (i.e., the third terminal 113) to the SW terminal (i.e., the second terminal 112) through the GND net (i.e., the third conductive net 123) and the SW net (i.e., the second conductive net 122). As shown in FIG. 5A and FIG. 5B, no matter which phase the Buck converter 400 is operating in, the SW net (i.e., the second conductive net 122) is active. By configuring the copper sink 104 to become part of the second conducive net 122, the current-carrying capacity of this busy net could be tremendously enhanced.

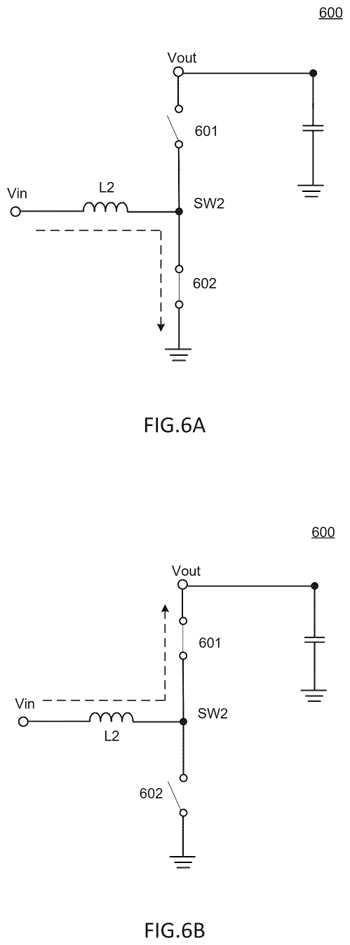

Now referring to FIG. 6A and FIG. 6B, an operation of a typical Boost converter 600 can also be described in terms of two main phases: the charging phase (e.g., FIG. 6A) and the discharging phase (e.g., FIG. 6B). The Boost converter 600 may include a first switch 601 and a second switch 602 that are connected in series between an output voltage Vout and a ground GND. The first switch 601 and the second switch 602 are connected at a second switch node SW2. An inductor L2 is connected between the second switch node SW2 and an intput voltage Vin. By manipulating one of the two switches to turn on and the other to turn off, either the output voltage Vout or the ground GND could be electrically connected to the second switch node SW2, and then conducts current flowing through the inductor L2.

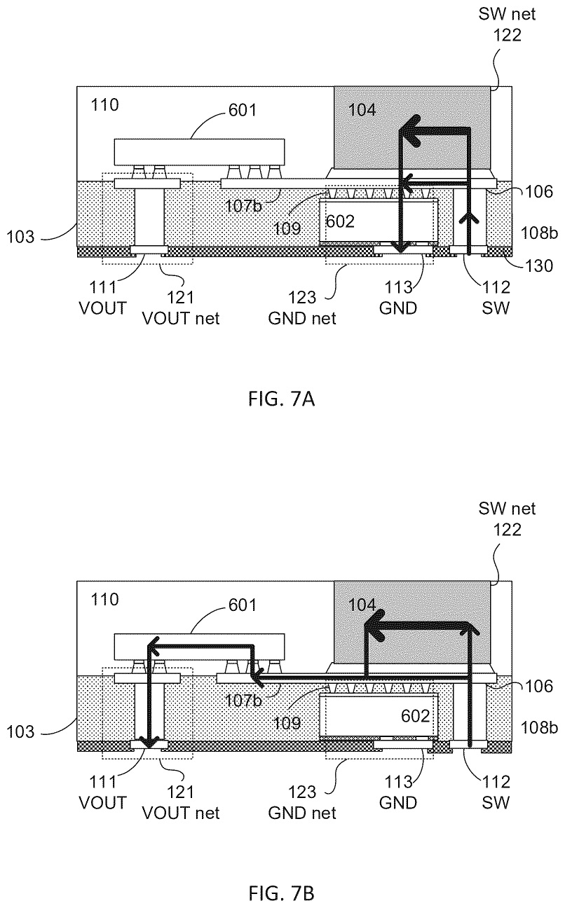

Referring to FIG. 7A and FIG. 7B, some reference numerals of FIG. 1 are replaced by reference numerals of circuit elements of the Boost converter 600 while others are kept the same. The power circuit package of this disclosure could be implemented for the Boost converter 600 and could reduce the overall on-resistance. The first die 101 of the package 100 could be a die including the first switch 601 of the Boost convertor 600, which may be a lateral FET device., The second die 102 of the package 100 could be a die including the second switch 602 of the Boost convertor 600, which may be a vertical FET device. Besides, the first terminal 111 could be configured to be coupled to the output voltage Vout and serve as a VOUT terminal of the power circuit package 100, making the first conductive net 121 become a VOUT net. The second terminal 112 could be configured to be coupled to the second switch node SW2 and serve as a SW terminal of the power circuit package 100, making the second conductive net 122 become a SW net. The third terminal 113 could be configured as GND terminal of the power circuit package 100, making the third conductive net 123 become a GND net. Other elements of the Boost convertor are not shown in FIG. 7A. For example, the second inductor L2, may be configured outside the power circuit package.

Referring to FIG. 7A, during the charging phase, the first switch 601 is turned off, so that the VOUT net (i.e., the first conductive net 121) is decoupled with the SW net (i.e., the second conductive net 122). The current flow all the way from the SW net (i.e., the second conductive net 122) to the GND terminal (i.e., the third terminal 113) through the SW net (i.e., the second conductive net 122) and the GND net (i.e., the third conductive net 123). Referring to FIG. 6B, during the discharging phase, the second switch 602 is turned off, so that the GND net (i.e., the third conductive net 123) is decoupled with the SW net (i.e., the second conductive net 122). The current flow all the way from the SW terminal (i.e., the second terminal 112) to the VOUT terminal (i.e., the first terminal 111) through the SW net (i.e., the second conductive net 122) and the VOUT net (i.e., the first conductive net 121). No matter which phase the Boost converter 600 is operating in, the SW net (i.e., the second conductive net 122) is active. By configuring the copper sink 104 to become part of this busy second conducive net 122, the conduction loss of this converter could be reduced.

How to assign roles to the first terminal 111, the second terminal 112 and third terminal 113 depends on how to arrange elements of the circuit in the package, the above implementations are just examples. Besides, the power circuit package 100 could be used to implement package structures for other circuits as well.

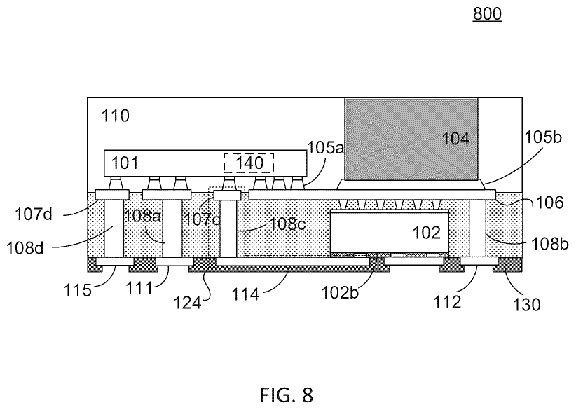

In the embodiments of FIG. 5 and FIG. 7, gate signals that control the first die and the second die may be provided from another die which is not shown in the package. However, in another embodiment of this disclosure, a controller may be integrated with switch device in the first die or in the second die and the package may further include a gate net. Referring to FIG. 8, the second patterned conductive layer 106 may further include a third pad 107c which is connected to electrodes of the first die 101 and coupled to a controller 140 integrated with the first switch in the first die 101. The first patterned conductive layer 120 may further include a fourth terminal 114 which is connected to electrodes of the second die 102 on its second side 102b. A fourth conductive via 108c is configured to electrically connected to the third pad 107c at one of its ends and electrically connected to the fourth terminal 114 at its another end, coupling the fourth terminal 114 to the first die 101 and the second die 102 and forming a gate net 124 of the power circuit package 100 together with them. As shown in FIG. 8, the fourth terminal 114 may not be exposed from a solder mask layer 130. In some embodiment, the first patterned conductive layer 120 may further include a fifth terminal 115 which may connected to electrodes of the first die 101 and serve as a GPIO terminal of the controller 140. A fifth conductive via 108d is configured to electrically connected to a fourth pad 107d at one of its ends and electrically connected to the fifth terminal 115 at its another end, coupling the fifth terminal 115 to the first die 101 and forming a GPIO net of the power circuit package 100 together with them.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A power circuit package, comprising:
a substrate having a first side and a second side opposite to the first side, the substrate comprising a first pattern conductive layer on the second side and a second pattern conductive layer on the first side;
wherein the first pattern conductive layer includes a first terminal, a second terminal and a third terminal;
a first die, arranged on the first side of the substrate and electrically coupled to the second pattern conductive layer;
a second die, embedded in the substrate and electrically coupled to the second pattern conductive layer;
a heat sink, arranged on the first side of the substrate and electrically coupled to the second pattern conductive layer;
wherein the first terminal is electrically coupled to the first die;
wherein the third terminal is electrically coupled to the second die;
wherein the second terminal is electrically coupled to the both the first die and the second die.

2. The power circuit package of claim 1, wherein the substrate includes a first conductive via embedded therein which is configured to electrically connected to the second pattern conductive layer at one of its ends and electrically connected to the first terminal at its another end and wherein the substrate includes a second conductive via embedded therein which is configured to electrically connected to the second pattern conductive layer at one of its ends and electrically connected to the second terminal at its another end.

3. The power circuit package of claim 2, wherein the substrate includes a third conductive via embedded therein which is configured to electrically connected to the second pattern conductive layer at one of its ends and electrically connected to the second die at its another end.

4. The power circuit package of claim 2, wherein the substrate includes a third conductive via embedded therein which is configured to electrically connected to the third terminal at one of its ends and electrically connected to the second die at its another end.

5. The power circuit package of claim 2, wherein the substrate further includes a fourth conductive via embedded therein which is configured to electrically connected the first die and the second die.

6. The power circuit package of claim 1, wherein the substrate further comprises a first conductive via, a second conductive via and a third conductive via embedded in the substrate and wherein the second pattern conductive layer includes a first pad and a second pad;
wherein the first pad, the first conductive via and the first terminal are electrically coupled and form a first conductive net of the package;
wherein the second pad, the second conductive via and the second terminal are electrically coupled and form a second conductive net of the package;
wherein the third conductive via, the third terminal and the second die are electrically coupled and form a third conductive net of the package;
wherein the first die, soldered to the first pad and second pad; and
wherein the heat sink, soldered to the second pad.

7. The power circuit package of claim 6, wherein the second pattern conductive layer further includes a third pad, the first pattern conductive layer further includes a fourth terminal, the substrate further includes a fourth conductive via, and wherein third pad, the fourth conductive via, the fourth terminal are electrically coupled and form a fourth conductive net of the package.

8. A power circuit package, comprising:
a substrate having a first side and a second side opposite to the first side, the substrate comprising a first pattern conductive layer on its second side and a second pattern conductive layer on its first side;
a first die having a lateral FET device therein, electrically coupled to the second pattern conductive layer;
a second die having a vertical FET device therein, embedded in the substrate and electrically coupled to the second pattern conductive layer;
a heat sink, electrically coupled to the second pattern conductive layer;
wherein the first pattern conductive layer includes a VIN terminal, an SW terminal and a GND terminal;
wherein the VIN terminal is configured to be coupled to an input voltage of a Buck convertor and the VIN terminal is electrically coupled to the first die;
wherein the GND is configured to be coupled to a ground voltage of the Buck convertor be and the this electrically coupled to the second die;
wherein the SW terminal is configured to be coupled to a switch node of the Buck convertor and is electrically coupled to the both the first die and the second die.

9. A power circuit package of claim 8, wherein the first die or the second die further includes a controller, the first pattern conductive layer further includes a fourth terminal, wherein the fourth terminal is configured to be coupled to the controller and the die that does not includes the controller among the first die and second die.

10. A power circuit package, comprising:
a substrate having a first side and a second side opposite to the first side, the substrate comprising a first pattern conductive layer on its second side and a second pattern conductive layer on its first side;
a first die having a lateral FET device therein, electrically coupled to the second pattern conductive layer;
a second die having a vertical FET device therein, embedded in the substrate and electrically coupled to the second pattern conductive layer;
a heat sink, electrically coupled to the second pattern conductive layer;
wherein the first pattern conductive layer includes a VOUT terminal, an SW terminal and a GND terminal;
wherein the VOUT terminal is configured to be coupled to an output voltage of a Boost convertor and the VOUT terminal is electrically coupled to the first die;
wherein the GND terminal is configured to be coupled to a ground voltage of the Boost convertor and the GND terminal is electrically coupled to the second die;
wherein the SW terminal is configured to be coupled to a switch node of the Boost convertor and is electrically coupled to the both the first die and the second die.

11. A power circuit package of claim 10, wherein the first die or the second die further includes a controller, the first pattern conductive layer further includes a fourth terminal, wherein the fourth terminal is configured to be coupled to the controller and the die that does not includes the controller among the first die and second die.
